(19) United States
(12) Patent Application Publication
(10) Pub. No.: US 2019/0056637 A1
(43) Pub. Date: Feb. 21, 2019

(54) In-Situ Passivation for Nonlinear Optical Crystals

(71) Applicant: KLA-Tencor Corporation, Milpitas, CA (US)

(72) Inventors: Mandar Paranjape, Cupertino, CA (US); Vladimir Dribinski, Scotts Valley, CA (US); Yung-Ho Alex Chuang, Cupertino, CA (US)

(21) Appl. No.: 16/036,724

(22) Filed: Jul. 16, 2018

Related U.S. Application Data
(60) Provisional application No. 62/548,187, filed on Aug. 21, 2017.

(51) Int. Cl. G02F 1/35; G02F 1/355; H01S 3/109; H01S 3/094; C30B 33/00; G01N 21/84

(52) U.S. Cl. CPC G02F 1/353; G02F 1/3551; G02F 1/3501; H01S 3/109; G01N 2021/8477; C30B 33/00; G01N 21/84; G02F 2001/3505; H01S 3/094

(57) ABSTRACT

In-situ passivation of a nonlinear optical (NLO) crystal during operation of a characterization tool includes converting a laser beam of a selected wavelength to a converted laser beam of a harmonic wavelength via a nonlinear optical (NLO) crystal and passivating the NLO crystal during conversion to the converted laser beam of the harmonic wavelength.

### CROSS-REFERENCE TO RELATED APPLICATIONS

The present application claims the benefit under 35 U.S.C. § 119(e) of U.S. Provisional Patent Application Ser. No. 62/548,187, filed Aug. 21, 2017, titled IN-SITU PASSIVATION OF THE NONLINEAR CRYSTALS DURING OPERATION, naming Mandar Paranjape, Vladimir Dribinski, and Yung-Ho Alex Chuang as inventors, which is incorporated herein by reference in the entirety.

### TECHNICAL FIELD

The present invention generally relates to the field of nonlinear optical materials and, more particularly, to a system and method for in-situ passivation of nonlinear optical crystals to cure crystal defects and related characterization tools incorporating the system and method for in-situ passivation of nonlinear optical crystals.

### BACKGROUND

Many modern-day laser systems require nonlinear optical (NLO) crystals. Laser systems commonly utilize NLO crystals for many applications such as frequency mixing, Raman amplification, Kerr-lens mode-locking, electro-optic modulation, acousto-optic modulation and the like.

Laser-induced damage (LID) of NLO crystals is a major limitation of many modern laser systems. LID occurs as a result of the interaction between laser radiation and the material making up a given NLO crystal. Exposure to electromagnetic radiation within a laser system may negatively impact various physical and optical properties of NLO crystals, such as, but not limited to, transmittance, reflectivity, and refraction. In turn, this degradation of physical properties due to accrued LID eventually leads to failure of NLO crystals within the given laser system.

LID becomes even more problematic in laser systems that utilize shorter wavelengths of the electromagnetic spectrum, with wavelengths less than 360 nm, such as deep ultraviolet (DUV) radiation. In addition, NLO crystals are more susceptible to LID when they have a greater quantity or amount of crystal defects, such as, but not limited to, dislocations, impurities, vacancies, and the like. Accordingly, the presence of crystal defects in NLO crystals leads to increased levels of LID and, in turn, shorter crystal lifetimes.

Therefore, it would be advantageous to provide a system and method that cures the shortcomings described above.

### SUMMARY

A system for passivating nonlinear optical (NLO) crystal defects is disclosed, in accordance with one or more embodiments of the present disclosure. In one embodiment, the system includes a purge gas source configured to provide a purge gas. In another embodiment, the system includes one or more flow control elements fluidically coupled to the purge gas source. In another embodiment, the one or more flow control elements are configured to control a flow of the purge gas. In another embodiment, the system includes an exposure chamber fluidically coupled to the one or more flow control elements via a purge gas inflow port and fluidically coupled to one or more purge gas elements via a purge gas outflow port. In another embodiment, the purge gas is configured to flow through the exposure chamber at a selected flow rate. In another embodiment, the system includes a nonlinear optical (NLO) crystal housed within the exposure chamber. In another embodiment, the NLO crystal is passivated by the purge gas as the purge gas flows through the exposure chamber. In another embodiment, the system includes at least one laser source configured generate and transmit a laser beam of a selected wavelength through the NLO crystal. In another embodiment, the NLO crystal is configured to generate a converted laser beam of a harmonic wavelength through frequency conversion during passivation of the NLO crystal. In another embodiment, the system includes a sample stage configured to secure a sample. In another embodiment, the sample is configured to receive at least a portion of the converted laser beam of the harmonic wavelength.

A system for passivating nonlinear optical (NLO) crystal defects is disclosed, in accordance with one or more embodiments of the present disclosure. In one embodiment, the system includes a hermetically-sealed exposure chamber including an enclosure configured to contain a volume of purge gas within an internal cavity. In another embodiment, the system includes a nonlinear optical (NLO) crystal housed within the internal cavity of the hermetically-sealed exposure chamber. In another embodiment, the NLO crystal is passivated by the purge gas contained within the hermetically-sealed exposure chamber. In another embodiment, the system includes at least one laser source configured generate and transmit a laser beam of a selected wavelength through the NLO crystal. In another embodiment, the NLO crystal is configured to generate a converted laser beam of a harmonic wavelength through frequency conversion during passivation of the NLO crystal. In another embodiment, the system includes a sample stage configured to secure a sample. In another embodiment, the sample is configured a sample configured to receive at least a portion of the converted laser beam of the harmonic wavelength.

A system for passivating nonlinear optical (NLO) crystal defects is disclosed, in accordance with one or more embodiments of the present disclosure. In one embodiment, the system includes a purge gas subsystem including a sealed purge gas pump. In another embodiment, the purge gas subsystem operates at a selected purge gas pressure. In another embodiment, the sealed purge gas pump is configured to recirculate purge gas through the purge gas subsystem at a selected flow rate. In another embodiment, the system includes an exposure chamber fluidically coupled to the purge gas subsystem via a purge gas inflow port and a purge gas outflow port. In another embodiment, the purge gas is configured to flow through the exposure chamber at the selected flow rate. In another embodiment, the system includes a nonlinear optical (NLO) crystal housed within the exposure chamber. In another embodiment, the NLO crystal is passivated by the purge gas as the purge gas flows through the exposure chamber. In another embodiment, the system includes at least one laser source configured generate and transmit a laser beam of a selected wavelength through the NLO crystal. In another embodiment, the NLO crystal is configured to generate a converted laser beam of a harmonic wavelength through frequency conversion during passivation of the NLO crystal. In another embodiment, the system includes a sample stage configured to secure a sample. In another embodiment, the sample is configured a sample configured to receive at least a portion of the converted laser beam of the harmonic wavelength.

A method for passivating nonlinear optical (NLO) crystal defects is disclosed, in accordance with one or more embodiments of the present disclosure. In one embodiment, the method may include, but is not limited to, pumping a purge gas through an exposure chamber including a nonlinear optical (NLO) crystal. In another embodiment, the method may include, but is not limited to, transmitting a laser beam of a selected wavelength into the exposure chamber. In another embodiment, the method may include, but is not limited to, converting the laser beam of the selected wavelength to a converted laser beam of a harmonic wavelength. In another embodiment, the method may include, but is not limited to, passivating the NLO crystal during conversion to the converted laser beam of the harmonic wavelength while the purge gas flows through the exposure chamber. In another embodiment, the method may include, but is not limited to, transmitting the converted laser beam of the harmonic wavelength from the exposure chamber.

A method for passivating nonlinear optical (NLO) crystal defects is disclosed, in accordance with one or more embodiments of the present disclosure. In one embodiment, the method may include, but is not limited to, pumping a purge gas into an exposure chamber including a nonlinear optical (NLO) crystal. In another embodiment, the method may include, but is not limited to, hermetically sealing the exposure chamber at a selected pressure. In another embodiment, the method may include, but is not limited to, transmitting a laser beam of a selected wavelength into the exposure chamber. In another embodiment, the method may include, but is not limited to, converting the laser beam of the selected wavelength to a converted laser beam of a harmonic wavelength. In another embodiment, the method may include, but is not limited to, passivating the NLO crystal during conversion to the converted laser beam of the harmonic wavelength while the exposure chamber is hermetically sealed. In another embodiment, the method may include, but is not limited to, transmitting the converted laser beam of the harmonic wavelength from the exposure chamber.

A method for passivating nonlinear optical (NLO) crystal defects is disclosed, in accordance with one or more embodiments of the present disclosure. In one embodiment, the method may include, but is not limited to, pumping a purge gas through an exposure chamber including a nonlinear optical (NLO) crystal at a selected purge gas pressure. In another embodiment, the method may include, but is not limited to, transmitting a laser beam of a selected wavelength into the exposure chamber. In another embodiment, the method may include, but is not limited to, converting the laser beam of the selected wavelength to a converted laser beam of a harmonic wavelength. In another embodiment, the method may include, but is not limited to, passivating the NLO crystal during conversion to the converted laser beam of the harmonic wavelength while the purge gas flows through the exposure chamber. In another embodiment, the method may include, but is not limited to, recirculating the purge gas in a purge gas system fluidically coupled to the exposure chamber during conversion to the converted laser beam of the harmonic wavelength. In another embodiment, the method may include, but is not limited to, transmitting the converted laser beam of the harmonic wavelength from the exposure chamber.

A system for characterizing a semiconductor device is disclosed, in accordance with one or more embodiments of the present disclosure. In one embodiment, the system includes a laser system. In another embodiment, the laser system includes an exposure chamber. In another embodiment, the laser system includes a nonlinear optical (NLO) crystal housed within the exposure chamber. In another embodiment, the nonlinear optical crystal is sufficiently passivated to establish a selected passivation level. In another embodiment, the laser system includes at least one laser source configured generate and transmit a laser beam of a selected wavelength through the NLO crystal. In another embodiment, the NLO crystal is configured to generate a converted laser beam of a harmonic wavelength through frequency conversion during passivation of the NLO crystal. In another embodiment, the system includes a sample stage configured to secure a sample. In another embodiment, the laser system is configured to illuminate at least a portion of a surface of the sample with the converted laser beam of the harmonic wavelength. In another embodiment, the system includes one or more detectors configured to receive at least a portion of illumination transmitted by the surface of the sample. In another embodiment, the system includes a controller. In another embodiment, the controller includes one or more processors and memory configured to store one or more sets of program instructions. In another embodiment, the one or more processors are configured to execute the one or more sets of program instructions. In another embodiment, the one or more sets of program instructions are configured to cause the one or more processors to obtain one or more images of the sample from the one or more detectors. In another embodiment, the one or more sets of program instructions are configured to cause the one or more processors to determine the presence or absence of one or more defects in the one or more images of the sample.

A method for characterizing a semiconductor device is disclosed, in accordance with one or more embodiments of the present disclosure. In one embodiment, the method may include, but is not limited to, converting a laser beam of a selected wavelength to a converted laser beam of a harmonic wavelength via a nonlinear optical (NLO) crystal. In another embodiment, the method may include, but is not limited to, passivating the NLO crystal during conversion to the converted laser beam of the harmonic wavelength. In another embodiment, the method may include, but is not limited to, transmitting the converted laser beam of the harmonic wavelength onto a surface of a sample. In another embodiment, the method may include, but is not limited to, obtaining one or more images of the sample. In another embodiment, the method may include, but is not limited to, determining the presence or absence of one or more defects in the one or more images of the sample.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the present disclosure may be better understood by those skilled in the art by reference to the accompanying figures in which:

FIG. 1 illustrates a simplified block diagram of a passivation system for in-situ passivation of nonlinear optical (NLO) crystals, in accordance with one or more embodiments of the present disclosure;

FIG. 2 illustrates a simplified block diagram of a passivation system for in-situ passivation of nonlinear optical (NLO) crystals, in accordance with one or more embodiments of the present disclosure;

FIG. 3 illustrates a simplified block diagram of a passivation system for in-situ passivation of nonlinear optical (NLO) crystals, in accordance with one or more embodiments of the present disclosure;

FIG. 4A illustrates a simplified flow diagram of a method for in-situ passivation of nonlinear optical (NLO) crystals, in accordance with one or more embodiments of the present disclosure;

FIG. 4B illustrates a simplified flow diagram of a method for in-situ passivation of nonlinear optical (NLO) crystals, in accordance with one or more embodiments of the present disclosure;

FIG. 4C illustrates a simplified flow diagram of a method for in-situ passivation of nonlinear optical (NLO) crystals, in accordance with one or more embodiments of the present disclosure;

FIG. 5 illustrates a simplified block diagram of a characterization tool for characterizing a wafer or a photomask/reticle, in accordance with one or more embodiments of the present disclosure; and

FIG. 6 illustrates a simplified flow diagram of a method for characterizing a wafer or a photomask/reticle, in accordance with one or more embodiments of the present disclosure.

### DETAILED DESCRIPTION OF THE INVENTION

Reference will now be made in detail to the subject matter disclosed, which is illustrated in the accompanying drawings.

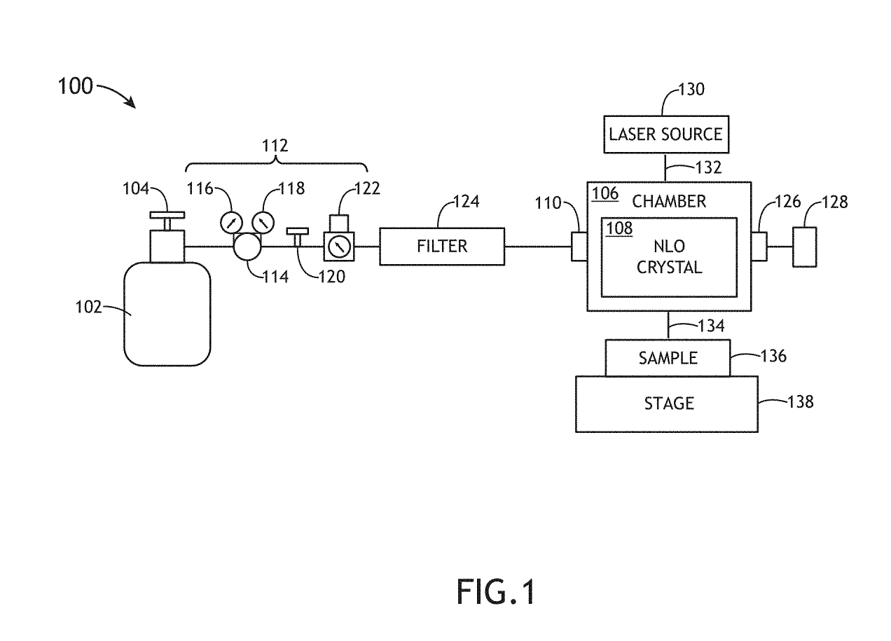

Referring generally to FIGS. 1-6, a system and method for in-situ passivation of nonlinear optical crystals is disclosed, in accordance with one or more embodiments of the present disclosure.

Systems and methods for producing (e.g., growing, mechanically preparing, and/or annealing) nonlinear optical (NLO) crystals are described in U.S. Pat. No. 9,250,178 to Chuang et al., issued on Feb. 2, 2016; U.S. Pat. No. 8,873,596 to Dribinski et al., issued on Oct. 28, 2014; U.S. Pat. No. 9,459,215 to Chuang et al., issued on Oct. 4, 2016; U.S. patent application Ser. No. 14/248,045 to Chuang et al., filed on Apr. 9, 2014; and U.S. patent application Ser. No. 15/284,231, to Chuang et al., filed on Oct. 3, 2016, which are each incorporated herein by reference in the entirety. It is noted herein that any of the methods and systems disclosed in the above applications may be used in combination with the methods and systems disclosed throughout the present disclosure.

As used throughout the present disclosure, the term “crystal”, “nonlinear crystal”, or “NLO crystal” generally refers to a nonlinear optical crystal suitable for frequency conversion. For purposes of the present disclosure, the NLO crystal may include, but is not limited to, beta-Barium Borate (BBO) nonlinear crystals, Lithium Triborate (LBO) nonlinear crystals, Cesium Lithium Borate (CLBO) nonlinear crystals, Cesium Borate (CBO) nonlinear crystals, Lithium Tetraborate (LTB) nonlinear crystals, oxide-type nonlinear crystals, or the like.

Nonlinear optical (NLO) crystals may be utilized for second, third, fourth, or fifth harmonic generations for all solid-state lasers typically using neodymium-based laser media (e.g., an Nd:YAG laser, an Nd:VO₄ laser, or the like). NLO crystals may be passivated to generate higher harmonics of a fundamental operation wavelength during operation. As used throughout the present disclosure, “in operation” or “during operation” may be defined as a period when the NLO crystal is held at a certain phase-matching temperature while a longer wavelength is focused on the NLO crystal and the NLO crystal emits a shorter wavelength at a higher frequency harmonic of the fundamental wavelength. For example, the NLO crystal may be configured to convert incident illumination of a first wavelength (e.g., 1064 nanometers (nm)) to an output illumination of a shorter wavelength (e.g., 532 nm, 355 nm, 266 nm, 213 nm, 193 nm, or the like) via frequency conversion.

Semiconductor devices may utilize high-power lasers with wavelength below 360 nm. At deep ultraviolet (DUV) wavelengths, the lifetime of an NLO crystal depends on the laser-induced damage (LID), such that damage generated by DUV wavelengths is a limiting factor to the lifespan of the NLO crystal.

NLO crystals utilized in frequency conversion are generally hygroscopic, (e.g., tend to absorb moisture from the air), and need to be kept dry during operation. Traditionally, processes for curing LID via passivation in NLO crystals focus primarily on containing an NLO crystal in a dry state. Typically, the purge gases utilized during the curing processes include clean dry air (CDA), dry nitrogen (N₂) gas, dry argon (Ar) gas, dry helium (He), or the like. The use of these types of gases may not provide improvements to the curing processes other than reducing hydration in the system.

Reducing hydrogen stress on the NLO crystal may improving NLO crystal quality by reducing crystal defects and inhomogeneity. In addition, high-power deep ultraviolet (DUV) radiation generates defect levels in NLO crystals, such as broken bonds or dangling bonds within the NLO crystal lattice. NLO crystals surfaces have more dangling bonds and larger electromagnetic fields on the exit surface of the NLO crystal (e.g., the surface where a laser beam exits the NLO crystal).

Ex-situ passivation (e.g., passivation outside of operation) with a hydrogen-based gas is known to mend dangling bonds both on the surface and interstitials of the NLO crystals. Ex-situ passivation, however, is limited to mending dangling bonds created by Alkali vacancies or dangling bonds created by hydrogen stress.

In contrast, in-situ passivation (e.g., passivation during operation) with a hydrogen-based gas mends broken bonds created by DUV generation and/or broken bonds created by nonlinear absorption during operation. It is noted herein that higher temperature and intense DUV beam may promote diffusion of the hydrogen in the crystal lattice, such that in-situ passivation using a hydrogen-based gas will improve the mending of LID in NLO crystals.

Embodiments of the present disclosure are directed to a system and method for in-situ passivation of nonlinear optical (NLO) crystals utilizing a hydrogen-based gas to purge NLO crystals during operation to generate a converted laser beam of a harmonic wavelength from a laser beam of a selected wavelength. Embodiments of the present disclosure are also directed to a system and method for characterizing a wafer or photomask/reticle utilizing a converted laser beam generated via frequency conversion of a laser beam of a selected wavelength with an NLO crystal.

FIGS. 1-3 generally illustrate a system for in-situ passivation of nonlinear optical crystals, in accordance with one or more embodiments of the present disclosure.

FIG. 1 illustrates a simplified block diagram of a passivation system 100 for in-situ passivation of nonlinear optical (NLO) crystals, in accordance with one or more embodiments of the present disclosure.

In one embodiment, the passivation system 100 includes a purge gas source 102 with a valve 104. For example, the purge gas source 102 may include a gas tank or cylinder. In another embodiment, the purge gas source 102 includes a purge gas (e.g., passivation gas, passivating gas, or the like). For example, the purge gas may include, but is not limited to, a hydrogen-based gas. For purposes of the present disclosure, a “hydrogen-based gas” may include any gas made up entirely or partially of hydrogen (e.g., atomic hydrogen gas (H) or diatomic hydrogen gas (H₂)), a low molecular weight compound of hydrogen (e.g., NH₃ or CH₄), an isotope of hydrogen (e.g., deuterium (D₂)) or a compound including an isotope of hydrogen (e.g., deuterated versions of NH₃ or CH₄). It is noted herein that the hydrogen-based component of the purge gas mixture being an isotope of hydrogen (e.g., deuterium) may result in improved passivation. In addition, it is noted herein the desired concentration of hydrogen or deuterium may include a concentration exceeding the natural abundance of hydrogen present under normal ambient conditions. Further, it is noted herein the desired concentration of hydrogen or deuterium may be a user selected concentration or a concentration determined utilizing one or more physical attributes of an NLO crystal. In this regard, only trace amounts of oxygen gas (e.g., less than 10 parts per million (ppm)) may be allowable in the purge gas to prevent ignition of the hydrogen-based gas.

By way of another example, the purge gas may include, but is not limited to, an inert gas. For purposes of the present disclosure, an “inert gas” may include any gas made up entirely or partially of helium gas, argon gas, nitrogen gas, or the like.

It is noted herein the purge gas may include a hydrogen-based gas concentration ranging from 0 percent to 20 percent, mixed with an inert gas concentration ranging from 80 percent to 100 percent. For example, the purge gas may include a hydrogen-based gas concentration ranging from 5 percent to 15 percent, mixed with an inert gas concentration ranging from 85 percent to 95 percent. For instance, purge gas may include a hydrogen-based gas concentration of 10 percent, mixed with an inert gas concentration of 90 percent.

It is noted herein that the above concentration ranges are not a limitation and are presented merely for purposes of illustration. In addition, it is noted herein that the exact concentration level of hydrogen-based gas in the purge gas mixture may be determined by optimizing, or at least improving passivation results above a selected level, and may vary from a fraction of the total hydrogen concentration to 100 percent of all the hydrogen in the mixture. It is contemplated that the hydrogen-based gas concentration level of the purge gas mixture may include any range suitable for the given application.

In another embodiment, the purge gas from the purge gas source 102 is supplied to an exposure chamber 106 including an NLO crystal 108. The exposure chamber 106 may protect the NLO crystal 104 from ambient atmospheric conditions and other impurities, thereby facilitating maintenance of its passivated condition. It is noted herein that a crystal exposed to atmospheric water and other impurities over time will begin to deteriorate and may revert back to an un-passivated state. Crystal exposure chambers (e.g., crystal housing units) are generally described in U.S. patent application Ser. No. 12/154,337 to Armstrong, filed May 6, 2008, which is incorporated herein by reference in the entirety.

In another embodiment, the purge gas enters the exposure chamber 106 via a purge gas inflow port 110. For example, the purge gas may enter the exposure chamber 106 via the purge gas inflow port 110 at a volumetric flow rate in excess of 10 cubic centimeters per minute (cc/min) (e.g., 10 millimeters/min (mL/min)).

In another embodiment, the valve 104 is fluidically coupled to one or more flow control elements 112. For example, the one or more flow control elements 112 may be configured to receive purge gas from the valve 104. By way of another example, the one or more flow control elements 112 may include, but are not limited to, a pressure regulator 114 including one or more of an upstream pressure gauge 116 and/or a downstream pressure gauge 118, an outlet pressure valve 120, a pressure regulator 122, or the like. The one or more flow control elements 112 may include a valve, regulator, or any other means for regulating the pressure or rate at which the purge gas moves through at least one conduit fluidically connecting the valve 104 of the purge gas source 102 to the exposure chamber 106. It is noted herein the one or more flow control elements 112 may regulate the purge gas flow rate to between 10 mL/min to 500 mL/min.

In another embodiment, the one or more flow control elements 112 are fluidically coupled to a contaminant filter 124. In another embodiment, a contaminant filter 124 is fluidically coupled to a purge gas inflow port 110 for an exposure chamber 106. For example, the purge gas inflow port 110 may be configured to receive purge gas from the contaminant filter 124, such that an interior cavity of the exposure chamber 106 is filled. By way of another example, the contaminant filter 124 may filter one or more organic particulates and/or one or more organic particulates from the purge gas.

In another embodiment, the exposure chamber 106 includes a purge gas outflow port 126. In another embodiment, the purge gas outflow port 126 is fluidically coupled to one or more purge gas elements 128. For example, the one or more purge gas elements 128 may be configured to receive purge gas from the purge gas outflow port 126. By way of another example, the one or more purge gas elements 128 may include, but are not limited to, a purge gas collector.

In another embodiment, the purge gas passes through the interior cavity of the exposure chamber 106 from the purge gas inflow port 110 to the purge gas outflow port 126, passivating the NLO crystal. In this regard, the NLO crystal 108 may be passivated through continuous flow of the purge gas through the exposure chamber 106.

In another embodiment, one or more laser sources 130 generate and transmit a laser beam 132 of a selected wavelength through the NLO crystal 108 in the exposure chamber 106. For example, the one or more laser sources 130 may include at least one electromagnetic source such as a neodymium-based laser media (e.g., an Nd:YAG laser, an Nd:VO₄ laser, or the like), a diode pumped solid state (DPSS) source, a fiber infrared (IR) source, or the like.

In another embodiment, the laser beam 132 are focused to an elliptical cross-section Gaussian beam waist in or proximate to the NLO crystal 108 using beam shaping optics. As used throughout the present disclosure, the term “proximate to” is preferably less than half of the Rayleigh range from the center of the NLO crystal 108. For example, the aspect ratio between the Gaussian widths of the principle axes of the ellipse may fall between about 2:1 and about 6:1. In another embodiment, the ratio between the principle axes of the ellipse may be between about 2:1 and about 10:1. By way of another example, the wider Gaussian width may be substantially aligned with the walk-off direction of the NLO crystal 108 (e.g. to within about 10 degrees of alignment). By way of another example, the input window 210 is set at a Brewster angle for the polarization of the laser beam 132.

In another embodiment, the beam-shaping optics include one or more anamorphic optics that change the cross section of the laser beam 132. For example, the one or more anamorphic optics may include, but are not limited to, at least one of a prism, a cylindrical curvature element, a radially-symmetric curvature element, and a diffractive element. By way of another example, the laser beam 132 may include a frequency in the infrared (IR) range (e.g., 1064 nm) or a frequency in the visible range (e.g. 532 nm) to be converted inside the NLO crystal 108. By way of another example, the laser beam 132 may include two or more frequencies to be combined inside the NLO crystal 108 to generate a sum or difference frequency. A description of frequency conversion and associated optics and hardware are described in U.S. Pat. No. 8,873,596 to Dribinski et al., issued on Oct. 28, 2014, which is incorporated previously herein by reference in the entirety.

In another embodiment, a converted laser beam 134 exits the exposure chamber 106, where the converted laser beam 134 is generated by transmitting the laser beam 132 through to the NLO crystal 108. For example, the converted laser beam 134 is of a harmonic wavelength to the selected wavelength of the laser beam 132. For instance, the converted laser beam 134 may include a frequency in the visible range (e.g., 532 nm) or a frequency in the ultraviolet (UV) or deep ultraviolet (DUV) ranges (e.g., 355 nm, 266 nm, 213 nm, 193 nm, or the like). It is noted herein the harmonic wavelength may be shorter than the selected wavelength.

In another embodiment, the converted laser beam 134 is transmitted onto a sample 136 (e.g., via one or more beam optics). In another embodiment, the sample 136 includes a sample suitable for characterization (e.g., inspection, review, imaging overlay metrology, or the like). For example, the sample 136 may include, but is not limited to, a photomask/reticle, a semiconductor wafer, or the like. As used throughout the present disclosure, the term “wafer” refers to a substrate formed of a semiconductor and/or a non-semiconductor material. In the case of a semiconductor material, the wafer may be formed from, but is not limited to, monocrystalline silicon, gallium arsenide, and/or indium phosphide. It is noted herein that many different types of devices may be formed on a wafer, and the term wafer as used herein is intended to encompass a wafer on which any type of device known in the art is being fabricated. Therefore, the above description should not be interpreted as a limitation on the scope of the present disclosure but merely an illustration.

In another embodiment, the sample 136 is secured via a sample stage 138. The sample stage 138 may include any appropriate mechanical and/or robotic assembly known in the art of semiconductor characterization. For example, the sample stage 138 may be configured to secure the sample 136 via contact with at least a portion of a front-side surface and/or a backside surface of the sample 136. For instance, the sample stage 138 may include, but is not limited to, a platform. By way of another example, the sample stage 138 may be configured to secure the sample 136 via contact with a thickness surface and/or an edge of the sample 136. For instance, the sample stage 138 may include, but is not limited to, one or more point contact devices.

The sample stage 138 may include an actuatable stage. For example, the sample stage 138 may include, but is not limited to, one or more translational stages suitable for selectively translating the sample 136 along one or more linear directions (e.g., x-direction, y-direction, and/or z-direction). By way of another example, the sample stage 138 may include, but is not limited to, one or more rotational stages suitable for selectively rotating the sample 136 along a rotational direction. By way of another example, the sample stage 138 may include, but is not limited to, one or more rotational stages and translational stages suitable for selectively translating the sample 136 along a linear direction and/or rotating the sample 136 along a rotational direction. By way of another example, the sample stage 138 may be configured to translate or rotate the sample 136 for positioning, focusing, and/or scanning in accordance with a selected characterization process (e.g., review, imaging overlay, or the like), several of which are known to the art.

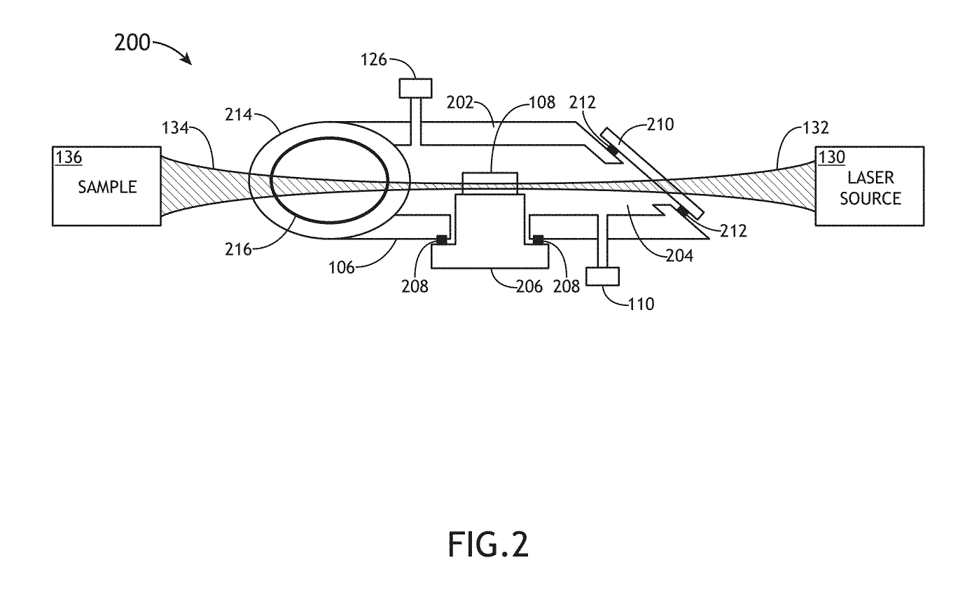

FIG. 2 illustrates a simplified block diagram of a passivation system 200, in accordance with one or more embodiments of the present disclosure.

In one embodiment, the passivation system 200 includes the exposure chamber 106. In another embodiment, the exposure chamber 106 includes an enclosure 202 including an internal cavity 204. For example, the enclosure 202 may be hermetically sealed. By way of another example, the enclosure 202 may be configured to contain a volume of purge gas within the internal cavity 204. For instance, the enclosure 202 may be configured to contain a volume of purge gas pressurized up to 15 PSI within the internal cavity 204.

In another embodiment, the exposure chamber 106 includes an NLO crystal stage 206 configured to support the NLO crystal 108 within the internal cavity 204 of the enclosure 202. In another embodiment, the exposure chamber 106 includes a hermetic stage seal 208 between the NLO crystal stage 206 and the enclosure 202. For example, the hermetic stage seal 208 may be fabricated from a material including, but not limited to, metal. For instance, the metal may be, but is not limited to, indium. It is noted herein, however, that the NLO crystal stage 206 may be a portion of an interior surface of the internal cavity 204. Therefore, the above description should not be interpreted as a limitation on the scope of the present disclosure but merely an illustration.

In another embodiment, the exposure chamber 106 includes the purge gas inflow port 110 and the purge gas outflow port 126. In another embodiment, the NLO crystal 108 is exposed to the purge gas contained within the internal cavity 204 of the enclosure 202 when the exposure chamber 106 is hermetically sealed. In this regard, the hermetic sealing of the exposure chamber 106 may reduce or eliminate the need to continually purge the NLO crystal 108 with a purge gas.

In another embodiment, the exposure chamber 106 includes an input window 210. For example, the input window 210 may be fabricated from a material including, but not limited to, calcium fluoride (CaF₂), glass, or the like. In another embodiment, the exposure chamber 106 includes a hermetic input window seal 212 between the input window 210 and the enclosure 202. For example, the hermetic input window seal 212 may be fabricated from a material including, but not limited to, metal. For instance, the metal may be, but is not limited to, indium.

In another embodiment, the one or more laser sources 130 generate and transmit the laser beam 132 through the NLO crystal 108 through the input window 210. In another embodiment, the enclosure 202 of the exposure chamber 106 is of a suitable size for housing the NLO crystal 108 and other components of a laser system (e.g., the one or more laser sources 130). It is noted herein, however, that the larger the enclosure, the more precautions that are needed for maintenance and repair of the laser system (e.g., to protect the NLO crystal 108 from degradation and maintain its passivated state). In this regard, the exposure chamber 106 may consist of a small enclosure 202 suitable for enclosing primarily only the NLO crystal 108.

In another embodiment, the exposure chamber 106 includes an output window 214. For example, the output window 214 may be fabricated from a material including, but not limited to, calcium fluoride (CaF₂), glass, or the like. In another embodiment, the exposure chamber 106 includes a hermetic output window seal 216 between the output window 214 and the enclosure 202. For example, the hermetic output window seal 216 may be fabricated from a material including, but not limited to, metal. For instance, the metal may be, but is not limited to, indium.

In another embodiment, the converted laser beam 134 exits the enclosure 202 via the output window 214, where the converted laser beam 134 is generated by transmitting the laser beam 132 through the NLO crystal 108. In another embodiment, the converted laser beam 134 is transmitted onto the sample 136 (e.g., via one or more beam optics).

In another embodiment, one or more of the input window 210 and/or the output window 214 may be set at a Brewster angle for the polarization of the laser beam 132 and/or the converted laser beam 134, respectively. It is noted herein that setting the output window 214 at the Brewster angle for the polarization of the converted laser beam 134 may maximize the transmission of the converted laser beam 134.

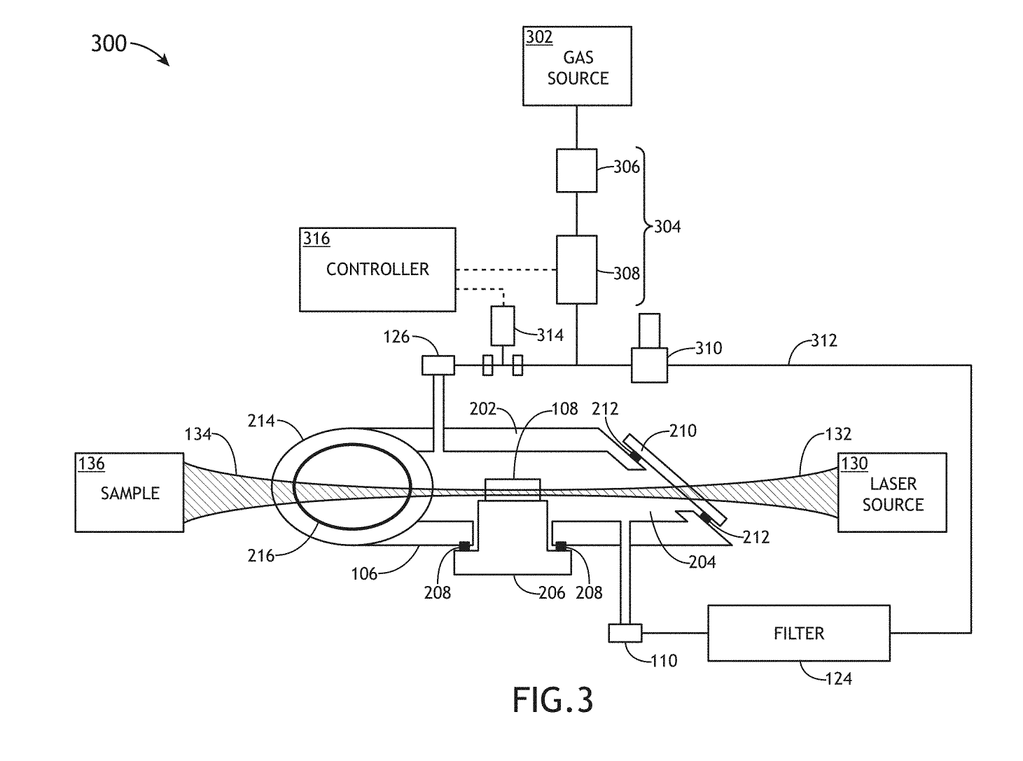

FIG. 3 illustrates a simplified block diagram of a passivation system 300 for in-situ passivation of NLO crystals, in accordance with one or more embodiments of the present disclosure.

In one embodiment, the passivation system 300 includes an input purge gas source 302. For example, the input purge gas source may include, but is not limited to, the purge gas source 102 with valve 104 of the passivation system 100. In another embodiment, the passivation system 300 includes one or more flow control elements 304 fluidically coupled to the purge gas source 302. For example, the one or more flow control elements 304 may include, but are not limited to, a pressure regulator 306, an electronic solenoid valve 308, or the like. By way of another example, the one or more flow control elements 304 may include any flow control element 106 utilized by the passivation system 100. The one or more flow control elements 304 may include a valve, regulator, or any other means for regulating the pressure or rate at which the purge gas moves through at least one conduit fluidically connecting the purge gas source 302 to the exposure chamber 106.

In another embodiment, the passivation system 300 includes a sealed purge gas pump 310 configured to receive and circulate gas through a purge gas system 312. For example, the purge gas pump 310 may be fluidically coupled to the one or more controller elements 304, such that new purge gas may be received by the sealed purge gas pump 310 from the input purge gas source 302. By way of another example, the purge gas pump 310 may be fluidically coupled to the purge gas outflow port 126 of the exposure chamber 106, such that reclaimed purge gas may be received by the sealed purge gas pump 310 from the purge gas outflow port 126. In this regard, the purge gas may be recirculated through the fluid system. It is noted herein the sealed purge gas pump 310 may regulate the purge gas flow rate to between 10 mL/min to 500 mL/min.

In another embodiment, the contaminant filter 124 is fluidically coupled to the sealed purge gas pump 310 and the purge gas inflow port 110 of the exposure chamber 106. For example, the contaminant filter 124 may receive purge gas from the sealed purge gas pump 310 and transmit the purge gas to the purge gas inflow port 110.

In another embodiment, an electronic pressure gauge 314 is fluidically coupled to the purge gas outflow port 126. For example, the electronic pressure gauge 314 may receive purge gas from the purge gas outflow port 126 and transmit the purge gas to the sealed purge gas pump 310 during recirculation of the purge gas.

In another embodiment, the passivation system 300 includes a controller 316. For example, the controller 316 may be communicatively coupled to one or more components of the passivation system 300 including, but not limited to, the electronic pressure gauge 314, the solenoid valve 308, the sealed gas purge pump 310, or the like. By way of another example, the controller 316 may include a flow controller configured to control the rate at which purge gas is supplied to the purge gas system 312. For instance, the controller 316 may be fluidically connected to the electronic pressure gauge 314 and configured to control the rate at which purge gas is supplied through the electronic solenoid valve 308 from the purge gas source 302. In addition, the controller 316 may be coupled to one or more of the purge gas inflow port 110 and/or the purge gas outflow port 126 of the exposure chamber 106 and be configured to control the rate at which purge gas enters and/or is removed, respectively, from the interior cavity 204 of the enclosure 202 of the exposure chamber 106.

In another embodiment, the controller 316 utilizes one or more flow control algorithms known in the art. For example, the flow control algorithm may direct the flow controller 316 to actuate one or more valves (e.g., the solenoid valve 308, the sealed gas purge pump 310), or the like based on a correlation between one or more mechanical properties of the one or more valves and a desired flow rate. For instance, a user-selected flow rate of 10 mL/min to 500 mL/min may be a desirable flow rate for passivating the NLO crystal 108 housed within the exposure chamber 106. It is noted herein that the above flow rate is not limiting and flow rates outside of this range may be desirable based on the purge gas mixture or the composition of the NLO crystal 108.

In one example, a standard operating configuration of the passivation system 300 may include the solenoid valve 308 being closed and the purge gas system 312 includes a purge gas pressurized up to 15 PSI. The pressurization of the purge gas may be set via the pressure regulator 306, and the electronic pressure gauge 314 may measure an operational purge gas pressure of the purge gas system 312. The controller 316 may calculate a difference between the operational purge gas pressure and a selected purge gas pressure. If the difference is below an acceptable PSI level (e.g., due to line leaks, or the like), the controller 316 may open the solenoid valve 308 to introduce new purge gas into the purge gas system 312. If the calculated difference is at an acceptable PSI level, it may close the solenoid valve 308. In this regard, purge gas may be conserved and operating cost of the passivation system 300 may be reduced.

Although the present disclosure is directed to a single controller 316, it is noted herein the passivation system 300 may include multiple controllers 316. Therefore, the above description should not be interpreted as a limitation on the scope of the present disclosure, but merely an illustration.

Although embodiments of the present disclosure describe the controller 316 as a component of the passivation system 300, it is noted herein that the controller 316 may not be an integral or required component of the passivation system 300. Therefore, the above description should not be interpreted as a limitation on the scope of the present disclosure but merely an illustration.

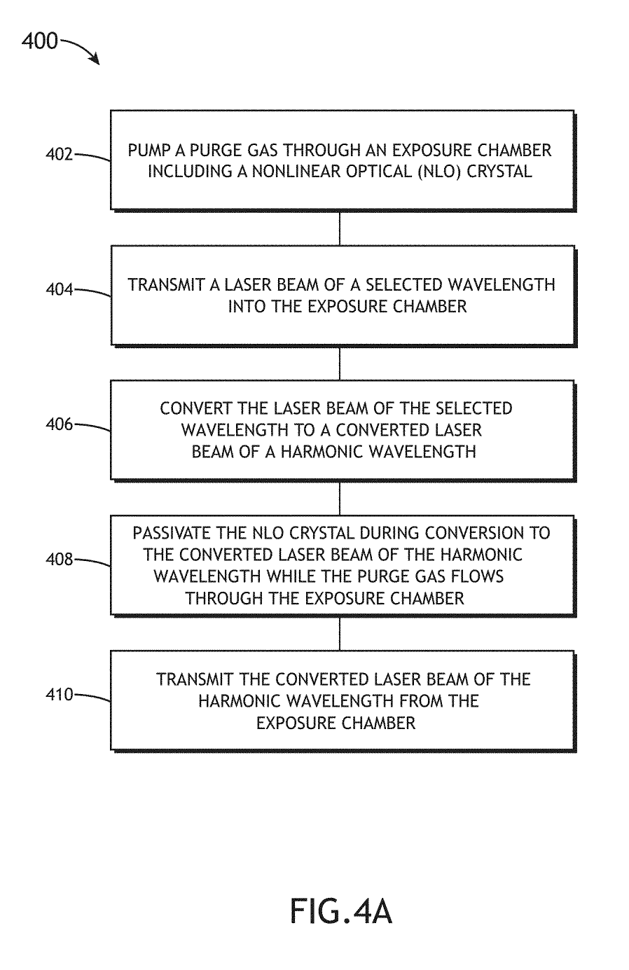

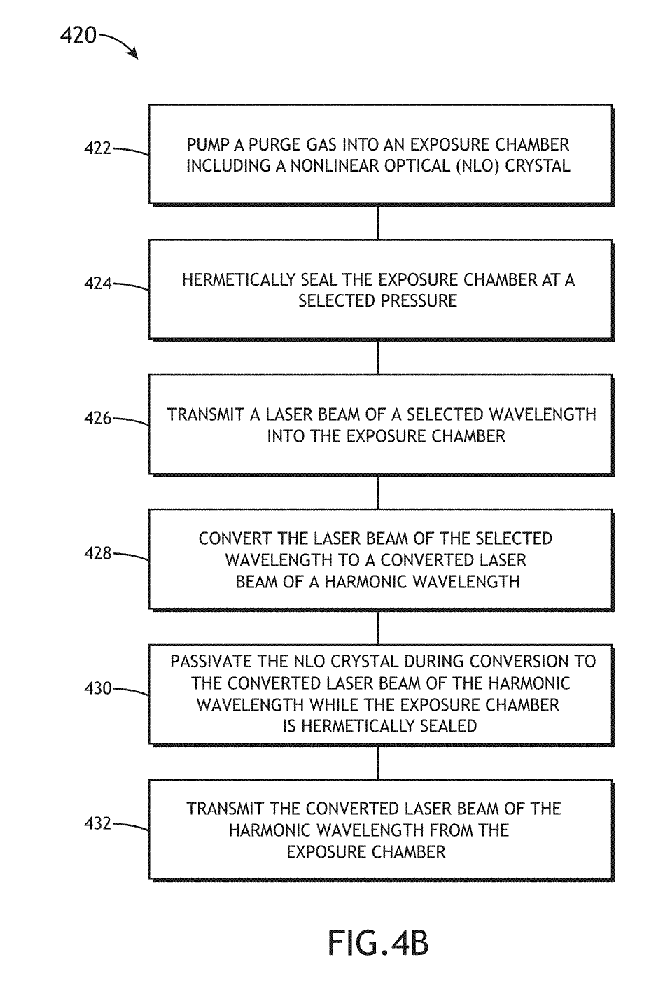

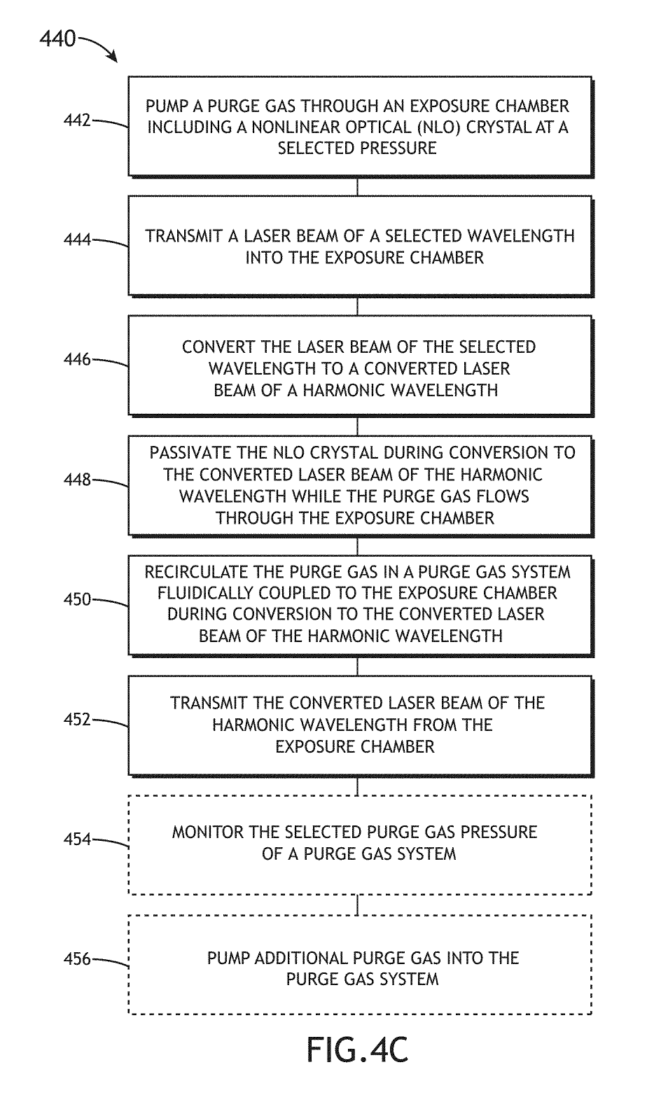

FIGS. 4A-4C generally illustrate a method for in-situ passivation of nonlinear optical crystals, in accordance with one or more embodiments of the present disclosure.

FIG. 4A illustrates a method 400 for in-situ passivation of nonlinear optical (NLO) crystals, in accordance with one or more embodiments of the present disclosure.

In step 402, a purge gas is pumped through an exposure chamber including a nonlinear optical (NLO) crystal. In one embodiment, the purge gas includes a hydrogen-based gas. For example, the purge gas may include 10 percent hydrogen-based gas and 90 percent inert gas. In another embodiment, the purge gas enters the exposure chamber 106 via the purge gas inflow port 110. In another embodiment, the purge gas exits the exposure chamber 106 via the purge gas outflow port 126 into the purge gas collector 128.

In step 404, a laser beam of a selected wavelength is transmitted into the exposure chamber. In one embodiment, the one or more laser sources 130 transmit the laser beam 132.

In step 406, the laser beam of the selected wavelength is converted to a converted laser beam of a harmonic wavelength. In one embodiment, the laser beam 132 is transmitted through the NLO crystal 108. For example, transmitting the laser beam 132 through the NLO crystal 108 may increase the frequency (and thus decrease the wavelength) of the laser beam 132, thus generating the converted laser beam 134.

In step 408, the NLO crystal is passivated during conversion to the converted laser beam of the harmonic wavelength while the purge gas flows through the exposure chamber. In one embodiment, laser-induced damage (LID) generated by the laser beam 132 on a surface and/or within a crystal lattice of the NLO crystal 108 are mended via passivation while the laser beam 132 is transmitted through the NLO crystal 108. In another embodiment, the purge gas continuously flows through the exposure chamber 106 at a selected flow rate, while passivating the NLO crystal. For example, the selected flow rate may range from 10 mL/min to 500 mL/min.

In step 410, the converted laser beam of the harmonic wavelength is transmitted from the exposure chamber. In one embodiment, the converted laser beam 134 of the harmonic wavelength is transmitted onto a surface of the sample 136.

FIG. 4B illustrates a method 420 for in-situ passivation of nonlinear optical (NLO) crystals, in accordance with one or more embodiments of the present disclosure.

In step 422, a purge gas is pumped into an exposure chamber including a nonlinear optical (NLO) crystal. In one embodiment, the purge gas includes a hydrogen-based gas. For example, the purge gas may include 10 percent hydrogen-based gas and 90 percent inert gas. In another embodiment, the purge gas enters the exposure chamber 106 via the purge gas inflow port 110.

In step 424, the exposure chamber is hermetically sealed at a selected pressure. For example, the selected pressure may be up to 15 PSI. In one embodiment, the exposure chamber 106 includes a set of hermetic seals. For example, the exposure chamber 106 may include the hermetic stage seal 208 between the holder 206 of the NLO crystal 108 and the enclosure 202, the hermetic input window seal 212 between the input window 210 and the enclosure 202, and/or the hermetic output window seal 216 between the output window 214 and the enclosure 202.

In step 426, a laser beam of a selected wavelength is transmitted into the exposure chamber. In one embodiment, the one or more laser sources 130 transmit the laser beam 132, where the laser beam 132 enters the enclosure 202 via the input window 210.

In step 428, the laser beam of the selected wavelength is converted to a converted laser beam of a harmonic wavelength. In one embodiment, the laser beam 132 is transmitted through the NLO crystal 108. For example, transmitting the laser beam 132 through the NLO crystal 108 may increase the frequency (and thus decrease the wavelength) of the laser beam 132, thus generating the converted laser beam 134.

In step 430, the NLO crystal is passivated during conversion to the converted laser beam of the harmonic wavelength while the exposure chamber is hermetically sealed. In one embodiment, laser-induced damage (LID) generated by the laser beam 132 on a surface and/or within a crystal lattice of the NLO crystal 108 are mended via passivation while the laser beam 132 is transmitted through the NLO crystal 108.

In step 432, the converted laser beam of the harmonic wavelength is transmitted from the exposure chamber. In one embodiment, the converted laser beam 134 exits the enclosure 202 via the output window 214.

FIG. 4C illustrates a method 440 for in-situ passivation of nonlinear optical (NLO) crystals, in accordance with one or more embodiments of the present disclosure.

In step 442, a purge gas is pumped into an exposure chamber including a nonlinear optical (NLO) crystal. In one embodiment, the purge gas includes a hydrogen-based gas. For example, the purge gas may include 10 percent hydrogen-based gas and 90 percent inert gas. In another embodiment, the purge gas is pumped through the purge gas system 312 via the sealed purge gas pump 310. In another embodiment, the purge gas enters the exposure chamber 106 via the purge gas inflow port 110. In another embodiment, the purge gas exits the exposure chamber 106 via the purge gas outflow port 126 and is transmitted to the sealed purge gas pump 310.

In step 444, a laser beam of a selected wavelength is transmitted into the exposure chamber. In one embodiment, the one or more laser sources 130 transmit the laser beam 132, where the laser beam 132 enters the enclosure 202 via the input window 210.

In step 446, the laser beam of the selected wavelength is converted to a converted laser beam of a harmonic wavelength. In one embodiment, the laser beam 132 is transmitted through the NLO crystal 108. For example, transmitting the laser beam 132 through the NLO crystal 108 may increase the frequency (and thus decrease the wavelength) of the laser beam 132, thus generating the converted laser beam 134.

In step 448, the NLO crystal is passivated during conversion to the converted laser beam of the harmonic wavelength while the purge gas flows through the exposure chamber. In one embodiment, laser-induced damage (LID) generated by the laser beam 132 on a surface and/or within a crystal lattice of the NLO crystal 108 are mended via passivation while the laser beam 132 is transmitted through the NLO crystal 108.

In step 450, the purge gas is recirculated in a purge gas system fluidically coupled to the exposure chamber during conversion to the converted laser beam of the harmonic wavelength. In one embodiment, the sealed purge gas pump 310 recirculates the purge gas within the purge gas system 312 and the exposure chamber 106.

In step 452, the converted laser beam of the harmonic wavelength is transmitted from the exposure chamber. In one embodiment, the high-frequency (or output) laser beam 222 exits the enclosure 202 via the output window 214 of the exposure chamber 106.

In optional step 454, the selected purge gas pressure of a purge gas system is monitored. In one embodiment, the purge gas is maintained at the selected pressure within the purge gas system 312 and the exposure chamber 106. For example, the pressurization of the purge gas may be set via the pressure regulator 306. By way of another example, the purge gas may be pressurized up to 15 PSI. In another embodiment, the electronic pressure gauge 314 measures an operational purge gas pressure of the purge gas system 312 and transmits the measurement to the controller 316. In another embodiment, the controller 316 calculates a difference between the operational purge gas pressure and a selected purge gas pressure, to determine whether the operational purge gas pressure is below a selected pressure threshold (e.g., deviates from the selected pressure by more than a determined allowable amount).

In optional step 456, additional purge gas is pumped into the purge gas system. In one embodiment, if the difference is below the selected pressure threshold (e.g., below an acceptable PSI level due to line leaks, or the like), the controller 316 opens the solenoid valve 308 to start a flow of additional purge gas into the purge gas system 312. In another embodiment, the controller 316 closes the solenoid valve 308 to stop the flow of the additional purge gas into the purge gas system 312 once the operational purge gas pressure of the purge gas system 312 is at or above the selected threshold (e.g., at an acceptable PSI level, having increased to within the allowable deviation from the selected purge gas pressure). In this regard, purge gas may be conserved and operating cost of the passivation system 300 may be reduced.

It is noted herein the methods, 400, 420, 440 are not limited to the steps provided. For example, the methods 400, 420, 440 may instead include more or fewer steps. By way of another example, the methods 400, 420, 440 may perform the steps in an order other than provided. Therefore, the above description should not be interpreted as a limitation on the scope of the present disclosure, but merely an illustration.

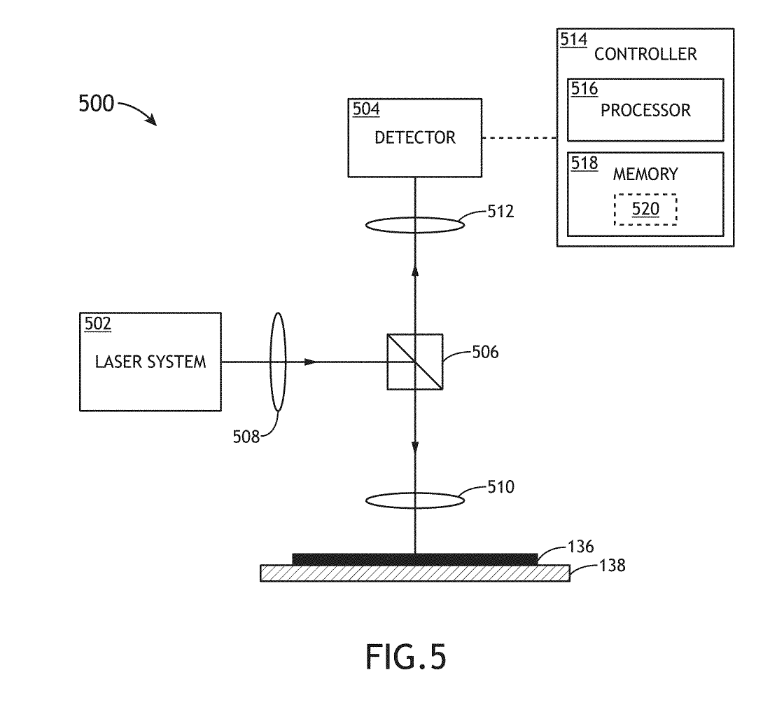

FIG. 5 illustrates a simplified block diagram of a characterization tool 500 for characterizing a wafer or a photomask/reticle, in accordance with one or more embodiments of the present disclosure.

The characterization tool 500 may include any optical characterization tool known in the art, such as, but not limited to, an inspection tool, review tool, imaging-based overlay metrology tool, a reflectometry-based characterization tool, an ellipsometry-based review tool or similar tool known in the art. It is noted herein that the characterization tool 500 may include any optical characterization tool configured to collect and analyze illumination reflected, scattered, diffracted, and/or radiated from a surface of the sample 136. For example, the optical characterization tool may include an optical characterization tool capable of generating one or more images and capable of operating at a wavelength ranging from IR light to DUV radiation (e.g., ranging from 180 nm to 1080 nm).

In one embodiment, the characterization tool 500 includes a laser system 502. For example, the laser system 502 may include a laser system. For example, the laser system may include, but is not limited to, the passivation system 100, the passivation system 200, and/or the passivation system 300.

It is noted herein the passivation system 100, the passivation system 200, and/or the passivation system 300 may be utilized in a semiconductor device characterization tool to as a high-intensity radiation source. For example, in-situ passivation of the NLO crystal within the passivation system 100, the passivation system 200, and/or the passivation system 300 may increase a lifetime of the NLO crystal utilized in frequency conversion. In this regard, the semiconductor device characterization tool may operate from longer before service maintenance is required. The laser system may include an NLO crystal 108 passivated to a selected degree of passivation that is acceptable for achieving desired physical/optical performance, improved LID resistance, improved output beam quality, improved output stability, increased crystal lifetime, or higher operating power.

In another embodiment, the sample 136 reflects, scatters, and/or diffracts radiation (e.g., a beam of illumination) impinging on the sample 136 from the laser system 502. In another embodiment, the characterization tool 500 includes one or more detectors 504. For example, the one or more detectors 504 may include any suitable detector known to the art, such as a charged coupled device (CCD) or a time-delay-and-integration (TDI) CCD based detector. In another embodiment, the one or more detectors 504 detect at least a portion of the radiation acquired from the sample 136. In another embodiment, measurements obtained via the detectors 504 include intensity variation in the portions of the radiation acquired from the sample 136. In another embodiment, the measurements are fitted and/or compared to reference data. For example, the reference data may be modelled, simulated, and/or experimentally obtained.

In another embodiment, the characterization tool 500 includes one or more beam splitters 506 suitable for focusing, suppressing, filtering, extracting, and/or directing (e.g., transmitting) at least a portion of the radiation received generated by the laser system 502 towards the surface of the sample 136, to a further component of an illumination path, or a component of a collection path. In another embodiment, the one or more beam splitters 506 include any optical device capable of splitting a beam of illumination into two or more beams of illumination.

In another embodiment, the characterization tool 500 includes one or more sets of optics. The one or more sets of optics may include any optical elements (e.g. retarders, quarter wave plates, focus optics, phase modulators, polarizers, mirrors, beam splitters, reflectors, converging/diverging lenses, prisms, etc.) configured to transmit at least a portion of illumination received directly or indirectly from the laser system 502 to the one or more detectors 504.

For example, the characterization tool 500 may include a set of one or more illumination optics 508 suitable for transmitting at least a portion of the radiation generated by the laser system 502 towards the surface of the sample 136 along the illumination path.

By way of another example, the characterization tool 500 may include a set of one or more collection optics 510 suitable for transmitting the at least a portion of the radiation acquired directly or indirectly by the surface of the sample 136 to the one or more beam splitters 506 along the collection path.

By way of another example, the characterization tool 500 may include a set of one or more collection optics 512 suitable for transmitting the at least a portion of the radiation acquired directly or indirectly by the one or more beam splitters 506 to the one or more detectors 504 along the collection path.

It is noted herein, however, that the characterization tool 500 may not include the one or more beam splitters 506, such that the characterization tool 500 includes a set of one or more collection optics suitable for transmitting the at least a portion of the radiation acquired directly or indirectly by the surface of the sample 136 to the one or more detectors 504 along the collection path. Therefore, the above description should not be interpreted as a limitation on the present disclosure but merely an illustration.

In another embodiment, the characterization tool 500 includes one or more polarizers. For example, radiation may be transmitted through the polarizers prior to illuminating the sample 136. By way of another example, the portions of the radiation acquired by the sample 136 may be transmitted through the polarizers prior to reaching the one or more detectors 504.

In another embodiment, the characterization tool 500 includes a controller 514. For example, the controller 514 may be communicatively coupled to one or more components of the characterization tool 500 (e.g., the one or more detectors 504, the laser system 502 or one or more components of the laser system 502, the stage 138, or the like).

In another embodiment, the controller 514 includes one or more processors 516 and memory 518. In another embodiment, the memory 518 stores one or more set of program instructions 520. In another embodiment, the one or more sets of program instructions 520 are configured to cause the one or more processors 516 to carry out any of the one or more processes described throughout the present disclosure.

The controller 514 may be configured to receive and/or acquire data or information from other systems or subsystems (e.g., one or more sets of information from the one or more detectors 504, the laser system 502 or one or more components of the laser system 502, the stage 138, or the like) of the characterization tool 500 via a transmission medium that may include wireline and/or wireless portions. The controller 514 may in addition be configured to transmit data or information (e.g., the output of one or more procedures of the inventive concepts disclosed herein) to one or more systems or subsystems (e.g., one or more sets of information from the one or more detectors 504, the laser system 502 or one or more components of the laser system 502, the stage 138, or the like) of the characterization tool 500 by a transmission medium that may include wireline and/or wireless portions. In this regard, the transmission medium may serve as a data link between the controller 514 and the other subsystems of the characterization tool 500. In addition, the controller 514 may be configured to send data to external systems via a transmission medium (e.g., network connection).

The one or more processors 516 may include any one or more processing elements known in the art. In this sense, the one or more processors 516 may include any microprocessor device configured to execute algorithms and/or program instructions 520. For example, the one or more processors 516 may consist of a desktop computer, mainframe computer system, workstation, image computer, parallel processor, handheld computer (e.g., tablet, smartphone, or phablet), or another computer system (e.g., networked computer). In general, the term “processor” may be broadly defined to encompass any device having one or more processing elements, which execute the one or sets of program instructions 520 from a non-transitory memory medium (e.g., the memory 518). Moreover, different subsystems of the characterization tool 500 (e.g., one or more sets of information from the one or more detectors 504, the laser system 502 or one or more components of the laser system 502, the stage 138, or the like) may include processor or logic elements suitable for carrying out at least a portion of the steps described throughout the present disclosure. Therefore, the above description should not be interpreted as a limitation on the present disclosure but merely an illustration.

The memory 518 may include any storage medium known in the art suitable for storing the one or more sets of program instructions 520 executable by the associated one or more processors 516. For example, the memory 518 may include a non-transitory memory medium. For instance, the memory 518 may include, but is not limited to, a read-only memory, a random access memory, a magnetic or optical memory device (e.g., disk), a magnetic tape, a solid state drive, and the like. The memory 518 may be configured to provide display information to a display device of a user interface. The memory 518 may in addition be configured to store user input information from a user input device of the user interface. The memory 518 may be housed in a common controller 514 housing with the one or more processors 516. The memory 518 may, alternatively or in addition, be located remotely with respect to the spatial location of the processors 516 and/or the controller 514. For instance, the one or more processors 516 and/or the controller 514 may access a remote memory 518 (e.g., server), accessible through a network (e.g., internet, intranet, and the like).

In another embodiment, a user interface is communicatively coupled to and/or integrated with the controller 514. In another embodiment, the user interface includes the display. In another embodiment, the user interface includes the user input device. In another embodiment, the display device is coupled to the user input device. For example, the display device may be coupled to the user input device by a transmission medium that may include wireline and/or wireless portions.

The display device may include any display device known in the art. For example, the display device may include, but is not limited to, a liquid crystal display (LCD). By way of another example, the display device may include, but is not limited to, an organic light-emitting diode (OLED) based display. By way of another example, the display device may include, but is not limited to a CRT display. Those skilled in the art should recognize that a variety of display devices may be suitable for implementation in the present invention and the particular choice of display device may depend on a variety of factors, including, but not limited to, form factor, cost, and the like. In a general sense, any display device capable of integration with a user input device (e.g., touchscreen, bezel mounted interface, keyboard, mouse, trackpad, and the like) is suitable for implementation in the present invention.

The user input device may include any user input device known in the art. For example, the user input device may include, but is not limited to, a keyboard, a keypad, a touchscreen, a lever, a knob, a scroll wheel, a track ball, a switch, a dial, a sliding bar, a scroll bar, a slide, a handle, a touch pad, a paddle, a steering wheel, a joystick, a bezel input device, or the like. In the case of a touchscreen interface, those skilled in the art should recognize that a large number of touchscreen interfaces may be suitable for implementation in the present invention. For instance, the display device may be integrated with a touchscreen interface, such as, but not limited to, a capacitive touchscreen, a resistive touchscreen, a surface acoustic based touchscreen, an infrared based touchscreen, or the like. In a general sense, any touchscreen interface capable of integration with the display portion of a display device is suitable for implementation in the present invention. In another embodiment, the user input device may include, but is not limited to, a bezel mounted interface.

It is noted herein that any description of the controller 514 may be extended to the controller 316 for purposes of the present disclosure. In addition, it is noted herein that any controller 514 utilized by the characterization tool 500 may be the same controller or a different controller from a controller utilized by the laser system 502 (e.g., the same controller or a different controller from the controller 316 utilized by the passivation system 300, where the laser system 502 is the passivation system 300). Therefore, the above description should not be interpreted as a limitation on the scope of the present disclosure, but merely an illustration.

Although the present disclosure is directed to a single controller 514, it is noted herein the characterization tool 500 may include multiple controllers 514. Therefore, the above description should not be interpreted as a limitation on the scope of the present disclosure but merely an illustration.

Although embodiments of the present disclosure describe the controller 514 as a component of the characterization tool 500, it is noted herein that the controller 514 may not be an integral or required component of the characterization tool 500. Therefore, the above description should not be interpreted as a limitation on the scope of the present disclosure but merely an illustration.

In another embodiment, the sample 136 is transferred between the characterization tool 500 and one or more process tools during the semiconductor production process. For example, the characterization tool 500 may perform the one or more semiconductor characterization processes before, between, and/or following one or more semiconductor fabrication processes performed by the one or more process tools. In another embodiment, defects determined via the one or more semiconductor characterization processes may be compensated for in subsequent fabrication processes on subsequent samples 136 and/or compensated for in subsequent fabrication processes on the same sample 136 (e.g., in the feed forward loop or the feedback loop). For example, the operating recipe, the one or more process tools, and/or the characterization tool 500 may be adjustable in a feed forward or a feedback loop based on the determined defects.

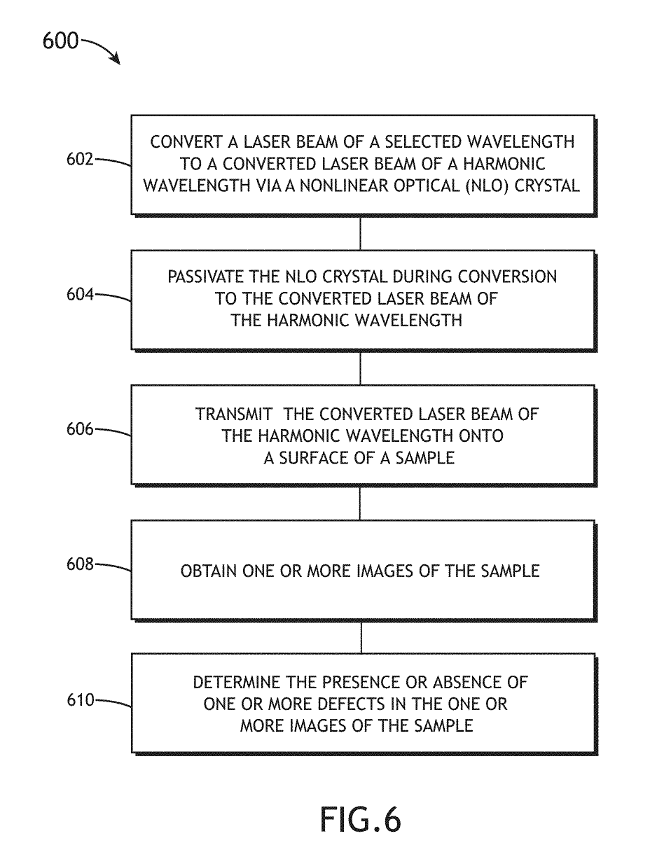

FIG. 6 illustrates a method 600 for characterizing a wafer or a photomask/reticle, in accordance with one or more embodiments of the present disclosure. It is noted herein the method 600 is not limited to the steps provided. For example, the method 600 may instead include more or fewer steps. By way of another example, the method 600 may perform the steps in an order other than provided. Therefore, the above description should not be interpreted as a limitation on the scope of the present disclosure, but merely an illustration.

In step 602, a laser beam of a selected wavelength is converted to a converted laser beam of a harmonic wavelength via a nonlinear optical (NLO) crystal. In step 604, the NLO crystal is passivated during conversion to the converted laser beam of the harmonic wavelength. In one embodiment, the characterization tool 500 includes a laser system 502 including an exposure chamber 106 housing a nonlinear optical (NLO) crystal 108 (e.g., the passivation system 100, the passivation system 200, the passivation system 300). In another embodiment, the laser system 502 performs one or more of the methods 400, 420, and/or 400.

In step 606, the converted laser beam of the harmonic wavelength is transmitted onto a surface of a sample. In one embodiment, at least a portion of the converted laser beam is transmitted onto a surface of the sample 136.

In step 608, one or more images of the sample are obtained. In one embodiment, the at least a portion of the converted laser beam is transmitted from the surface of the sample 136 to the one or more detectors 504, where the one or more detectors 504 obtain the one or more images.

In step 610, the presence or absence of one or more defects is determined in the one or more images of the sample. In one embodiment, the one or more images are transmitted to the controller 516, which determines whether the one or more defects are present or absent from the one or more images.

Advantages of the present disclosure include a system and method for in-situ passivation of nonlinear optical (NLO) crystals utilizing a hydrogen-based gas to purge NLO crystals during operation to generate a converted laser beam of a harmonic wavelength from a laser beam of a selected wavelength. Advantages of the present disclosure also include a system and method for characterizing a wafer or photomask/reticle utilizing a converted laser beam generated via frequency conversion of a laser beam of a selected wavelength with an NLO crystal.

Those having skill in the art will recognize that the state of the art has progressed to the point where there is little distinction left between hardware, software, and/or firmware implementations of aspects of systems; the use of hardware, software, and/or firmware is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be effected (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations will typically employ optically-oriented hardware, software, and or firmware.

In some implementations described herein, logic and similar implementations may include software or other control structures. Electronic circuitry, for example, may have one or more paths of electrical current constructed and arranged to implement various functions as described herein. In some implementations, one or more media may be configured to bear a device-detectable implementation when such media hold or transmit device-detectable instructions operable to perform as described herein. In some variants, for example, implementations may include an update or modification of existing software or firmware, or of gate arrays or programmable hardware, such as by performing a reception of or a transmission of one or more instructions in relation to one or more operations described herein. Alternatively or in addition, in some variants, an implementation may include special-purpose hardware, software, firmware components, and/or general-purpose components executing or otherwise invoking special-purpose components. Specifications or other implementations may be transmitted by one or more instances of tangible transmission media as described herein, optionally by packet transmission or otherwise by passing proximate to distributed media at various times.

Alternatively, or in addition, implementations may include executing a special-purpose instruction sequence or invoking circuitry for enabling, triggering, coordinating, requesting, or otherwise causing one or more occurrences of virtually any functional operations described herein. In some variants, operational or other logical descriptions herein may be expressed as source code and compiled or otherwise invoked as an executable instruction sequence. In some contexts, for example, implementations may be provided, in whole or in part, by source code, such as C++, or other code sequences. In other implementations, source or other code implementation, using commercially available and/or techniques in the art, may be compiled/ /implemented/translated/converted into a high-level descriptor language (e.g., initially implementing described technologies in C, C++, python, Ruby on Rails, Java, PHP, .NET, or Node.js programming language and thereafter converting the programming language implementation into a logic-synthesizable language implementation, a hardware description language implementation, a hardware design simulation implementation, and/or other such similar mode(s) of expression). For example, some or all of a logical expression (e.g., computer programming language implementation) may be manifested as a Verilog-type hardware description (e.g., via Hardware Description Language (HDL) and/or Very High Speed Integrated Circuit Hardware Descriptor Language (VHDL)) or other circuitry model which may then be used to create a physical implementation having hardware (e.g., an Application Specific Integrated Circuit). Those skilled in the art will recognize how to obtain, configure, and optimize suitable transmission or computational elements, material supplies, actuators, or other structures in light of these teachings.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link (e.g., transmitter, receiver, transmission logic, reception logic, etc.), etc.).

In a general sense, those skilled in the art will recognize that the various embodiments described herein can be implemented, individually and/or collectively, by various types of electro-mechanical systems having a wide range of electrical components such as hardware, software, firmware, and/or virtually any combination thereof; and a wide range of components that may impart mechanical force or motion such as rigid bodies, spring or torsional bodies, hydraulics, electro-magnetically actuated devices, and/or virtually any combination thereof. Consequently, as used herein “electro-mechanical system” includes, but is not limited to, electrical circuitry operably coupled with a transducer (e.g., an actuator, a motor, a piezoelectric crystal, a Micro Electro Mechanical System (MEMS), etc.), electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of memory (e.g., random access, flash, read only, etc.)), electrical circuitry forming a communications device (e.g., a modem, communications switch, optical-electrical equipment, etc.), and/or any non-electrical analog thereto, such as optical or other analogs. Those skilled in the art will also appreciate that examples of electro-mechanical systems include but are not limited to a variety of consumer electronics systems, medical devices, as well as other systems such as motorized transport systems, factory automation systems, security systems, and/or communication/computing systems. Those skilled in the art will recognize that electro-mechanical as used herein is not necessarily limited to a system that has both electrical and mechanical actuation except as context may dictate otherwise.

In a general sense, those skilled in the art will recognize that the various aspects described herein which can be implemented, individually and/or collectively, by a wide range of hardware, software, firmware, and/or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of memory (e.g., random access, flash, read only, etc.)), and/or electrical circuitry forming a communications device (e.g., a modem, communications switch, optical-electrical equipment, etc.). Those having skill in the art will recognize that the subject matter described herein may be implemented in an analog or digital fashion or some combination thereof.

Those skilled in the art will recognize that at least a portion of the devices and/or processes described herein can be integrated into a data processing system. Those having skill in the art will recognize that a data processing system generally includes one or more of a system unit housing, a video display device, memory such as volatile or non-volatile memory, processors such as microprocessors or digital signal processors, computational entities such as operating systems, drivers, graphical user interfaces, and applications programs, one or more interaction devices (e.g., a touch pad, a touch screen, an antenna, etc.), and/or control systems including feedback loops and control motors (e.g., feedback for sensing position and/or velocity; control motors for moving and/or adjusting components and/or quantities). A data processing system may be implemented utilizing suitable commercially available components, such as those typically found in data computing/communication and/or network computing/communication systems.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken limiting.

Although a user is described herein as a single figure, those skilled in the art will appreciate that the user may be representative of a human user, a robotic user (e.g., computational entity), and/or substantially any combination thereof (e.g., a user may be assisted by one or more robotic agents) unless context dictates otherwise. Those skilled in the art will appreciate that, in general, the same may be said of “sender” and/or other entity-oriented terms as such terms are used herein unless context dictates otherwise.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, different other components. It is to be understood that such depicted architectures are merely exemplary, and that in fact many other architectures may be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components, and/or wirelessly interactable, and/or wirelessly interacting components, and/or logically interacting, and/or logically interactable components.

In some instances, one or more components may be referred to herein as “configured to,” “configurable to,” “operable/operative to,” “adapted/adaptable,” “able to,” “conformable/conformed to,” etc. Those skilled in the art will recognize that such terms (e.g., “configured to”) can generally encompass active-state components and/or inactive-state components and/or standby-state components, unless context requires otherwise.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although various operational flows are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

Although particular embodiments of this invention have been illustrated, it is apparent that various modifications and embodiments of the invention may be made by those skilled in the art without departing from the scope and spirit of the foregoing disclosure. It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Accordingly, the scope of the invention should be limited only by the claims appended hereto.

What is claimed:

1. A system for passivating nonlinear optical (NLO) crystal defects, comprising:
a purge gas source configured to provide a purge gas;
one or more flow control elements fluidically coupled to the purge gas source, wherein the one or more flow control elements are configured to control a flow of the purge gas;
an exposure chamber fluidically coupled to the one or more flow control elements via a purge gas inflow port and fluidically coupled to one or more purge gas elements via a purge gas outflow port, wherein the purge gas is configured to flow through the exposure chamber at a selected flow rate;
a nonlinear optical (NLO) crystal housed within the exposure chamber, wherein the NLO crystal is passivated by the purge gas as the purge gas flows through the exposure chamber;
at least one laser source configured generate and transmit a laser beam of a selected wavelength through the NLO crystal, wherein the NLO crystal is configured to generate a converted laser beam of a harmonic wavelength through frequency conversion during passivation of the NLO crystal; and
a sample stage configured to secure a sample, wherein the sample is configured to receive at least a portion of the converted laser beam of the harmonic wavelength.

2. The system in claim 1, wherein the purge gas includes:
at least one of hydrogen, deuterium, a hydrogen-based compound, or a deuterium-based compound.

3. The system in claim 2, wherein the purge gas includes:
a low molecular weight hydrogen compound.

4. The system in claim 3, wherein the purge gas includes:
at least one of H₂, D₂, NH₃, or CH₄.

5. The system in claim 2, wherein the purge gas includes:
at least one of hydrogen, deuterium, a hydrogen-based compound, or a deuterium-based compound at a selected concentration mixed with an inert gas at a selected inert gas concentration.

6. The system in claim 5, wherein the selected concentration of the at least one of hydrogen, deuterium, the hydrogen-based compound, or the deuterium-based compound is in a range of 5 percent to 15 percent; wherein the selected inert gas concentration of the inert gas is in a range of 85 percent to 95 percent.

7. The system in claim 6, wherein the selected concentration of the at least one of hydrogen, deuterium, the hydrogen-based compound, or the deuterium-based compound is 10 percent; wherein the selected inert gas concentration of the inert gas is in a range of 90 percent.

8. The system in claim 1, wherein the laser beam operates at a selected wavelength in the range of 532 nanometers to 1064 nanometers.

9. The system in claim 8, wherein the converted laser beam operates at a harmonic wavelength in the range of 193 nanometers to 532 nanometers.

10. The system in claim 9, wherein the converted laser beam operates at a harmonic wavelength in the range of 193 nanometers to 266 nanometers.

11. The system in claim 1, wherein the at least one laser source includes a neodymium-based laser media.

12. The system in claim 1, wherein the selected flow rate of the purge gas is in a range of 10 millimeters per minute and 500 milliliters per minute.

13. The system in claim 1, further comprising:
a contaminant filter fluidically coupled to the one or more flow control elements and the purge gas inflow port, the contaminant filter configured to remove at least one of organic particulates or inorganic particulates from the purge gas.

14. A system for passivating nonlinear optical (NLO) crystal defects, comprising:
a hermetically-sealed exposure chamber including an enclosure configured to contain a volume of purge gas within an internal cavity;
a nonlinear optical (NLO) crystal housed within the internal cavity of the hermetically-sealed exposure chamber, wherein the NLO crystal is passivated by the purge gas contained within the hermetically-sealed exposure chamber;
at least one laser source configured generate and transmit a laser beam of a selected wavelength through the NLO crystal, wherein the NLO crystal is configured to generate a converted laser beam of a harmonic wavelength through frequency conversion during passivation of the NLO crystal; and
a sample stage configured to secure a sample, wherein the sample is configured to receive at least a portion of the converted laser beam of the harmonic wavelength.

15. The system in claim 14, the hermetically-sealed exposure chamber comprising:
an input window, wherein a hermetic input window seal is positioned between the input window and the enclosure, wherein the laser beam of the selected wavelength is transmitted through the input window.

16. The system in claim 14, the hermetically-sealed exposure chamber comprising:
an output window, wherein a hermetic output window seal is positioned between the output window and the enclosure, wherein the converted laser beam of the harmonic wavelength is transmitted through the output window.

17. The system in claim 14, the hermetically-sealed exposure chamber comprising:
an NLO crystal stage configured to support the NLO crystal within the internal cavity, wherein a hermetic stage seal is positioned between the NLO crystal stage and the enclosure.

18. A system for passivating nonlinear optical (NLO) crystal defects, comprising:
a purge gas subsystem including a sealed purge gas pump, wherein the purge gas subsystem operates at a selected purge gas pressure, wherein the sealed purge gas pump is configured to recirculate purge gas through the purge gas subsystem at a selected flow rate;
an exposure chamber fluidically coupled to the purge gas subsystem via a purge gas inflow port and a purge gas outflow port, wherein the purge gas is configured to flow through the exposure chamber at the selected flow rate;
a nonlinear optical (NLO) crystal housed within the exposure chamber, wherein the NLO crystal is passivated by the purge gas as the purge gas flows through the exposure chamber;
at least one laser source configured generate and transmit a laser beam of a selected wavelength through the NLO crystal, wherein the NLO crystal is configured to generate a converted laser beam of a harmonic wavelength through frequency conversion during passivation of the NLO crystal; and
a sample stage configured to secure a sample, wherein the sample is configured to receive at least a portion of the converted laser beam of the harmonic wavelength.

19. The system in claim 18, the purge gas subsystem comprising:
a purge gas source configured to provide a purge gas; and
one or more flow control elements fluidically coupled to the purge gas source and the sealed purge gas pump, wherein the one or more flow control elements include at least an electronic solenoid valve.

20. The system in claim 19, the purge gas subsystem comprising:
an electronic pressure gauge fluidically coupled to the purge gas outflow port and the sealed purge gas pump.

21. The system in claim 20, comprising:
a controller, wherein the controller includes one or more processors and memory configured to store one or more sets of program instructions, wherein the one or more processors are configured to execute the one or more sets of program instructions, wherein the one or more sets of program instructions are configured to cause the one or more processors to:
monitor the selected pressure of the purge gas system; and
pump additional purge gas into the purge gas system.

22. The system in claim 21, wherein the one or more sets of program instructions are configured to cause the one or more processors to monitor the selected pressure within the purge gas system via:
determination of a difference between an operational purge gas pressure received from the electronic pressure gauge and the selected purge gas pressure.

23. The system in claim 22, wherein the one or more sets of program instructions are configured to cause the one or more processors to pump the additional purge gas into the purge gas system via:
opening of the electronic solenoid valve if the determined difference is below the selected pressure threshold, wherein the opening of the electronic solenoid valve starts a flow of the additional purge gas from the purge gas source to the purge gas subsystem; and
closing of the electronic solenoid valve if the determined difference is at least the selected pressure threshold, wherein the closing of the electronic solenoid valve stops the flow of the additional purge gas from the purge gas source to the purge gas subsystem.

24. The system in claim 18, the purge gas subsystem comprising:
a contaminant filter fluidically coupled to the sealed purge gas pump and the purge gas inflow port, the contaminant filter configured to remove at least one of organic particulates or inorganic particulates from the purge gas.

25. A method for passivating nonlinear optical (NLO) crystal defects comprising:
pumping a purge gas through an exposure chamber including a nonlinear optical (NLO) crystal;
transmitting a laser beam of a selected wavelength into the exposure chamber;
converting the laser beam of the selected wavelength to a converted laser beam of a harmonic wavelength;
passivating the NLO crystal during conversion to the converted laser beam of the harmonic wavelength while the purge gas flows through the exposure chamber; and
transmitting the converted laser beam of the harmonic wavelength from the exposure chamber.

26. A method for passivating nonlinear optical (NLO) crystal defects comprising:
pumping a purge gas into an exposure chamber including a nonlinear optical (NLO) crystal;
hermetically sealing the exposure chamber at a selected pressure;
transmitting a laser beam of a selected wavelength into the exposure chamber;
converting the laser beam of the selected wavelength to a converted laser beam of a harmonic wavelength;
passivating the NLO crystal during conversion to the converted laser beam of the harmonic wavelength while the exposure chamber is hermetically sealed; and
transmitting the converted laser beam of the harmonic wavelength from the exposure chamber.

27. A method for passivating nonlinear optical (NLO) crystal defects comprising:
pumping a purge gas through an exposure chamber including a nonlinear optical (NLO) crystal at a selected purge gas pressure;
transmitting a laser beam of a selected wavelength into the exposure chamber;
converting the laser beam of the selected wavelength to a converted laser beam of a harmonic wavelength;
passivating the NLO crystal during conversion to the converted laser beam of the harmonic wavelength while the purge gas flows through the exposure chamber;
recirculating the purge gas in a purge gas system fluidically coupled to the exposure chamber during conversion to the converted laser beam of the harmonic wavelength; and
transmitting the converted laser beam of the harmonic wavelength from the exposure chamber.

28. The method in claim 27, further comprising:
monitoring the selected purge gas pressure of a purge gas system.

29. The method in claim 28, the monitoring the selected purge gas pressure of the purge gas system comprising:
receiving an operational purge gas pressure within the purge gas system; and
determining a difference between the operational purge gas pressure and the selected purge gas pressure.

30. The method in claim 29, further comprising:
pumping additional purge gas into the purge gas system.

31. The method in claim 30, the pumping the additional purge gas into the purge gas system comprising:
starting a flow of the additional purge gas into the purge gas system if the determined difference is below the selected pressure threshold; and
stopping the flow of the additional purge gas into the purge gas system if the determined difference is at or above the selected pressure threshold.

32. A system for characterizing a semiconductor device, comprising:
a laser system, comprising:
an exposure chamber;
a nonlinear optical (NLO) crystal housed within the exposure chamber, wherein the nonlinear optical crystal is sufficiently passivated to establish a selected passivation level; and
at least one laser source configured generate and transmit a laser beam of a selected wavelength through the NLO crystal, wherein the NLO crystal is configured to generate a converted laser beam of a harmonic wavelength through frequency conversion during passivation of the NLO crystal;
a sample stage configured to secure a sample, wherein the laser system is configured to illuminate at least a portion of a surface of the sample with the converted laser beam of the harmonic wavelength;
one or more detectors configured to receive at least a portion of illumination transmitted by the surface of the sample; and
a controller, wherein the controller includes one or more processors and memory configured to store one or more sets of program instructions, wherein the one or more processors are configured to execute the one or more sets of program instructions, wherein the one or more sets of program instructions are configured to cause the one or more processors to:
obtain one or more images of the sample from the one or more detectors; and
determine the presence or absence of one or more defects in the one or more images of the sample.

33. The system in claim 32, wherein the laser system further comprises:
a purge gas source configured to provide a purge gas;
one or more flow control elements fluidically coupled to the purge gas source, wherein the one or more flow control elements are configured to control a flow of the purge gas,
wherein the exposure chamber is fluidically coupled to the one or more flow control elements via a purge gas inflow port and fluidically coupled to one or more purge gas elements via a purge gas outflow port, wherein the purge gas is configured to flow through the exposure chamber at a selected flow rate, wherein the NLO crystal is passivated by the purge gas as the purge gas flows through the exposure chamber.

34. The system in claim 32, wherein the exposure chamber is hermetically sealed, wherein the exposure chamber includes an enclosure configured to contain a volume of purge gas within an internal cavity configured to contain a volume of purge gas, wherein the NLO crystal is passivated by the volume of purge gas contained within the hermetically-sealed exposure chamber.

35. The system in claim 32, wherein the laser system further comprises:
a purge gas subsystem including a sealed purge gas pump, wherein the purge gas subsystem operates at a selected purge gas pressure, wherein the sealed purge gas pump is configured to recirculate purge gas through the purge gas subsystem at a selected flow rate,
wherein the exposure chamber is fluidically coupled to the purge gas subsystem via a purge gas inflow port and a purge gas outflow port, wherein the purge gas is configured to flow through the exposure chamber at the selected flow rate, wherein the NLO crystal is passivated by the purge gas as the purge gas flows through the exposure chamber.

36. The system in claim 32, wherein the sample includes at least one of a semiconductor wafer, a photomask, or a reticle.

37. The system in claim 32, further comprising:
one or more illumination optics configured to direct illumination from the laser system along an illumination path to the surface of the sample.

38. The system in claim 32, further comprising:
one or more collection optics configured to direct illumination transmitted from the surface of the sample along a collection path to the one or more detectors.

39. A method for characterizing a semiconductor device comprising:
converting a laser beam of a selected wavelength to a converted laser beam of a harmonic wavelength via a nonlinear optical (NLO) crystal;
passivating the NLO crystal during conversion to the converted laser beam of the harmonic wavelength;
transmitting the converted laser beam of the harmonic wavelength onto a surface of a sample;
obtaining one or more images of the sample; and
determining the presence or absence of one or more defects in the one or more images of the sample.
